(19) United States
(12) Patent Application Publication
(10) Pub. No.: US 2023/0395638 A1
(43) Pub. Date: Dec. 7, 2023

(54) PHOTOELECTRIC CONVERSION APPARATUS, METHOD FOR MANUFACTURING PHOTOELECTRIC CONVERSION APPARATUS, DEVICE, AND SUBSTRATE

(71) Applicant: CANON KABUSHIKI KAISHA, Tokyo (JP)

(72) Inventor: TSUTOMU TANGE, Kanagawa (JP)

(21) Appl. No.: 18/328,351

(22) Filed: Jun. 2, 2023

(30) Foreign Application Priority Data
Jun. 6, 2022 (JP) 2022-091508

(51) Int. Cl. H01L 27/146

(52) U.S. Cl. CPC H01L 27/14636; H01L 27/14634; H01L 27/1469; H01L 27/14645

(57) ABSTRACT

A photoelectric conversion apparatus includes a semiconductor layer having a front surface and a back surface and including a photoelectric conversion unit, a circuit substrate, a first insulating film, a second insulating film, a third insulating film, and a wiring layer. The first insulating film includes at least one of silicon oxide and silicon oxycarbide. The second insulating film includes at least one of silicon carbide, silicon nitride, and silicon carbonitride. A hole portion provided with a conductive material and penetrating through the first insulating film and the second insulating film is disposed. An entire end portion of the hole portion on the semiconductor layer side of the second insulating film is in contact with the third insulating film.

### BACKGROUND OF THE INVENTION

### Field of the Invention

The present disclosure relates to a photoelectric conversion apparatus, a method for manufacturing the photoelectric conversion apparatus, a device, and a substrate.

### Description of the Related Art

In order to achieve miniaturization, high sensitivity, multi-functionality, and the like in photoelectric conversion apparatuses, a lamination type sensor has been discussed in which a pixel substrate including a photoelectric conversion unit and a circuit substrate including a signal processing circuit, such as an analog-to-digital (AD) conversion circuit, are laminated. According to Japanese Patent Application Laid-Open No. 2020-145427, a technique is discussed that uses hydrogen termination of dangling bonds for a lamination type sensor to reduce noise and dark current resulting from influence of a crystal defect in silicon and/or an interface state between silicon and an insulating film.

In a lamination type sensor including hybrid bonding between metals and that between silicon oxides, a pixel substrate and a circuit substrate are formed in different processes, and then bonded. The processes after bonding affects each of the pixel substrate and the circuit substrate, so that restrictions on the process increase. Thus, it can be considered that a heat treatment process for promoting diffusion of hydrogen is performed in a process before bonding.

However, in the lamination type sensor according to Japanese Patent Application Laid-Open No. 2020-145427, heat treatment is performed on the pixel substrate alone in a state where vias formed in an electrode pad and a dummy pad that are connected to a wiring layer including metal. Thus, there is a possibility that the wiring layer including the metal is oxidized.

### SUMMARY OF THE INVENTION

The present disclosure is directed to the provision of a photoelectric conversion apparatus that can reduce noise and dark current resulting from influence of a crystal defect in silicon and/or an interface state between silicon and an insulating film while reducing oxidation of a wiring layer including a metal in heat treatment.

According to an aspect of the present description, a photoelectric conversion apparatus includes a semiconductor layer having a front surface and a back surface and including a photoelectric conversion unit between the front surface and the back surface, a circuit substrate arranged closer to the front surface than to the back surface, a first insulating film arranged between the front surface and the circuit substrate, a second insulating film arranged between the front surface and the first insulating film, a third insulating film arranged between the front surface and the second insulating film, and a wiring layer arranged between the front surface and the second insulating film, wherein the first insulating film includes at least one of silicon oxide and silicon oxycarbide, wherein the second insulating film includes at least one of silicon carbide, silicon nitride, and silicon carbonitride, wherein a hole portion provided with a conductive material and penetrating through the first insulating film and the second insulating film is disposed, and wherein an entire end portion of the hole portion on the semiconductor layer side of the second insulating film is in contact with the third insulating film.

Further features of the present disclosure will become apparent from the following description of exemplary embodiments with reference to the attached drawings.

### BRIEF DESCRIPTION OF THE DRAWINGS

FIG. 1 is a schematic diagram illustrating a structure of a photoelectric conversion apparatus according to a first exemplary embodiment.

FIG. 2 is a schematic diagram illustrating a structure of a photoelectric conversion apparatus according to a modification of the first exemplary embodiment.

FIGS. 3A, 3B, 3C, 3D, 3E, 3F, 3G, and 3H are schematic diagrams illustrating a manufacturing method for the photoelectric conversion apparatus in FIG. 1.

FIG. 4 is a schematic diagram illustrating the manufacturing method for the photoelectric conversion apparatus in FIG. 1.

FIGS. 5A, 5B, and 5C are schematic diagrams illustrating the manufacturing method for the photoelectric conversion apparatus in FIG. 1.

FIGS. 6A, 6B, and 6C are schematic diagrams illustrating configurations of devices according to a second exemplary embodiment.

### DESCRIPTION OF THE EMBODIMENTS

Exemplary embodiments according to the present disclosure will be described below with reference to the accompanying drawings. The exemplary embodiments described below are not intended to limit the scope of the present disclosure as encompassed by the appended claims. A plurality of features is described in the exemplary embodiments, but not all of the plurality of features is essential to the present disclosure, and the plurality of features may be freely combined. Further, in the accompanying drawings, the same or similar configurations are denoted by the same reference numerals, and a redundant description is omitted. According to each of the exemplary embodiments described below, a complementary metal oxide semiconductor (CMOS) sensor is mainly described as an example of a photoelectric conversion apparatus. However, each of the exemplary embodiments is not limited to a CMOS sensor and can be applied to other examples of a photoelectric conversion apparatus. For example, the photoelectric conversion apparatus includes a charge coupled device (CCD), an image capturing apparatus, a ranging apparatus (an apparatus for measuring a distance using focus detection or time of flight (TOF)), and a photometric apparatus (an apparatus for measuring an incident light amount).

In a case where it is described that “a member A and a member B are electrically connected” in the present specification, it is not limited to a case where the member A and the member B are directly connected. For example, even if another member C is connected between the members A and B, it is sufficient that they are electrically connected.

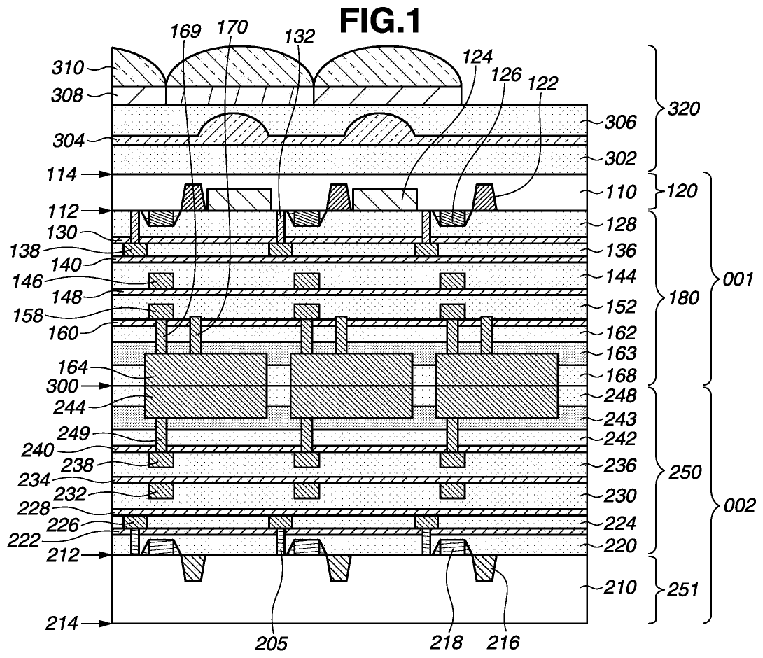

A first exemplary embodiment of the present disclosure will be described below. A photoelectric conversion apparatus and a manufacturing method thereof according to the present exemplary embodiment are described with reference to FIGS. 1 to 5C.

Initially, an outline configuration of the photoelectric conversion apparatus according to the present exemplary embodiment is described with reference to FIG. 1. FIG. 1 is a schematic cross-sectional view of the photoelectric conversion apparatus according to the present exemplary embodiment.

The photoelectric conversion apparatus according to the present exemplary embodiment includes a pixel substrate 001, a circuit substrate 002, and an optical structure 320 as illustrated in FIG. 1. The circuit substrate 002 includes a first semiconductor layer 251 and a first wiring structure 250, and the first semiconductor layer 251 includes a first semiconductor substrate 210. The pixel substrate 001 includes a second semiconductor layer 120 and a second wiring structure 180, and the second semiconductor layer 120 includes a second semiconductor substrate 110. The first semiconductor layer 251 includes a pair of a first front surface 212 and a first back surface 214 that form opposite outer surfaces. The first wiring structure 250, the second wiring structure 180, the second semiconductor layer 120, and the optical structure 320 are laminated in this order on the first front surface 212 side of the first semiconductor layer 251.

The first semiconductor layer 251 includes a signal processing unit, such as an analog-to-digital (AD) conversion circuit unit. The first semiconductor layer 251 also includes a first contact plug 205, a first element isolation unit 216, and a metal oxide semiconductor (MOS) transistor including a first gate electrode 218.

The first wiring structure 250 includes insulating films 220, 222, 224, 228, 230, 234, 236, 240, 242, 243, and 248 laminated in this order from the first semiconductor layer 251 side, and a plurality of wiring layers arranged in the insulating films. FIG. 1 illustrates first wiring layers 226, 232, 238, and 244 arranged on different insulating films among the plurality of wiring layers made of a conductive material including metals, such as copper and cobalt.

The second wiring structure 180 includes insulating films 168, 163, 162, 160, 152, 148, 144, 140, 136, 130, and 128 laminated in this order from the first semiconductor layer 251 side, and a plurality of wiring layers arranged in the insulating films. FIG. 1 illustrates second wiring layers 138, 146, 158, and 164 arranged on different insulating films among the plurality of wiring layers made of the conductive material including metals, such as copper and cobalt.

The second wiring structure 180 and the first wiring structure 250 are laminated in such a manner that the insulating films 168 and 248 face each other, and the first wiring layer 244 of the first wiring structure 250 and the second wiring layer 164 of the second wiring structure 180 are electrically connected.

Among the insulating films forming the first wiring structure 250 and the second wiring structure 180, the insulating films 128, 136, 144, 152, 162, 168, 220, 224, 230, 236, 242, and 248 generally include an insulating material having a relatively low relative permittivity from the viewpoint of reducing inter-wiring capacitance. An insulating material having a relatively low relative permittivity includes, for example, a first insulating material, such as silicon oxide and silicon oxycarbide.

Thus, the insulating films 128, 136, 144, 152, 162, 168, 220, 224, 230, 236, 242, and 248 include at least one of silicon oxide and silicon oxycarbide. The first insulating material has a property of being permeable to hydrogen.

Meanwhile, the insulating films 130, 140, 148, 160, 163, 222, 228, 234, 240, and 243 each have a role as an etching stopper film at the time of forming the first wiring layers 226, 232, 238, and 244 and the second wiring layers 138, 146, 158, and 164 and a role as a diffusion prevention film for a wiring material. An insulating material that fulfills these roles includes, for example, a second insulating material, such as silicon carbide, silicon carbonitride, and silicon nitride.

Thus, the insulating films 130, 140, 148, 160, 163, 222, 228, 234, 240, and 243 include at least one of silicon carbide, silicon nitride, and silicon carbonitride. The second insulating material has a low hydrogen permeability and has a property of inhibiting diffusion of hydrogen.

As described above, the first wiring structure 250 and the second wiring structure 180 each include a laminated member which is formed by laminating a plurality of the insulating films including the insulating material that is permeable to hydrogen and a plurality of the insulating films including the insulating material that inhibits diffusion of hydrogen. The first insulating material is more permeable to hydrogen than the second insulating material.

The second semiconductor layer 120 includes a pair of a second front surface 112 and a second back surface 114 that form opposite outer surfaces. The second semiconductor layer 120 is in contact with the second wiring structure 180 on the second front surface 112, and the circuit substrate 002 is arranged on the second front surface 112 side of the second semiconductor layer 120. A photoelectric conversion unit 124 and a second element isolation unit 122 are provided between the second front surface 112 and the second back surface 114.

A second contact plug 132 and a MOS transistor including a second gate electrode 126 are provided on the second front surface 112 side of the second semiconductor layer 120.

The photoelectric conversion unit 124 may be a photodiode that accumulates a charge, an avalanche photodiode that amplifies a charge, or a single photon avalanche diode (SPAD) using an avalanche photodiode. A plurality of pixels is arranged in an array and forms a pixel region. The optical structure 320 may be provided on the second back surface 114 side of the second semiconductor layer 120.

The optical structure 320 may include an insulating film 302, an interlayer lens 304, an insulating film 306, a color filter layer 308, and a microlens 310 that are provided in this order from the second back surface 114 side of the second semiconductor layer 120. The interlayer lens 304, the color filter layer 308, and the microlens 310 may be provided for each of the plurality of pixels.

According to the present exemplary embodiment in FIG. 1, the insulating film 162 arranged between the second front surface 112 and the circuit substrate 002 is referred to as, for example, a first insulating film. The insulating film 160 arranged between the second front surface 112 and the first insulating film 162 is referred to as, for example, a second insulating film. The insulating film 152 arranged between the second front surface 112 and the second insulating film 160 is referred to as, for example, a third insulating film. The insulating film 163 arranged between the circuit substrate 002 and the first insulating film 162 is referred to as, for example, a fourth insulating film. In different exemplary embodiments, the correspondence relationship are not limited to this relationship.

As described above, the photoelectric conversion apparatus according to the present exemplary embodiment is a laminated sensor and also a back-illuminated sensor.

In the photoelectric conversion apparatus according to the present exemplary embodiment, a second via 169 and a hole portion 170 are provided to penetrate through the first insulating film 162, the second insulating film 160, and the fourth insulating film 163. The second via 169 provided with the conductive material including metals, such as copper and cobalt, is in contact with the second wiring layer 158 arranged between the second front surface 112 and the second insulating film 160. Thus, the second via 169 and the second wiring layer 158 are electrically connected.

Meanwhile, the hole portion 170 is provided in such a manner that an entire end portion of the hole portion 170 on the second semiconductor layer 120 side of the second insulating film 160 is in contact with the third insulating film 152. Thus, the hole portion 170 and the second wiring layer 158 are not electrically connected. A conductive material including metals, such as copper and cobalt, or an insulating material, such as silicon oxide, may be arranged in the hole portion 170. The conductive material including metals, such as copper and cobalt, arranged in the hole portion 170 may be the same as or different from the conductive material arranged in the second wiring layers 138, 146, 158, and 164. In a case where the conductive material including metals, such as copper and cobalt, is arranged in the hole portion 170, improvement in mechanical strength and heat release efficiency in the pixel substrate 001 is expected as compared with a case where the insulating material, such as silicon oxide, is arranged.

One of the causes of noise and dark current occurring near the photoelectric conversion unit 124 is influence of a crystal defect in the second semiconductor layer 120 and a dangling bond at an interface between the second semiconductor layer 120 and the insulating film 128. For this matter, a technique is known that uses hydrogen termination of dangling bonds to reduce noise and dark current near the photoelectric conversion unit 124.

Hydrogen can be supplied to the dangling bond, for example, from an insulating film including hydrogen. According to the present exemplary embodiment, for example, the insulating films 128, 136, 144, 152, 162, 163, and 168 have a property of supplying hydrogen and is useable as hydrogen supply sources.

Here, the insulating films 130, 140, 148, 160, and 163 that include the second insulating material inhibit diffusion of hydrogen. However, the second wiring layers 138, 146, and 158 are each electrically connected by vias (not illustrated), and contact portions between the vias and the second wiring layers 138, 146, and 158 serve as supply paths for hydrogen from the insulating films 128, 136, 144, and 152. In addition to a role as the hydrogen supply source, the fourth insulating film 163 has the roles as the etching stopper film at the time of forming the second wiring layer 164 and as the diffusion prevention film for a wiring material, and also has the property of inhibiting the diffusion of hydrogen.

In a case where hydrogen is supplied from the insulating films 128, 136, 144, 152, 162, 163, and 168 to the photoelectric conversion unit 124, it is desirable to perform heat treatment for promoting the diffusion of hydrogen.

The heat treatment may be performed in a nitrogen atmosphere or a hydrogen-containing atmosphere (e.g., a forming gas atmosphere). It is desirable that the heat treatment for promoting the diffusion of hydrogen is performed in a state in which the film serving as the hydrogen supply source is formed, in other words, after formation of the insulating films 128, 136, 144, 152, 162, 163, and 168.

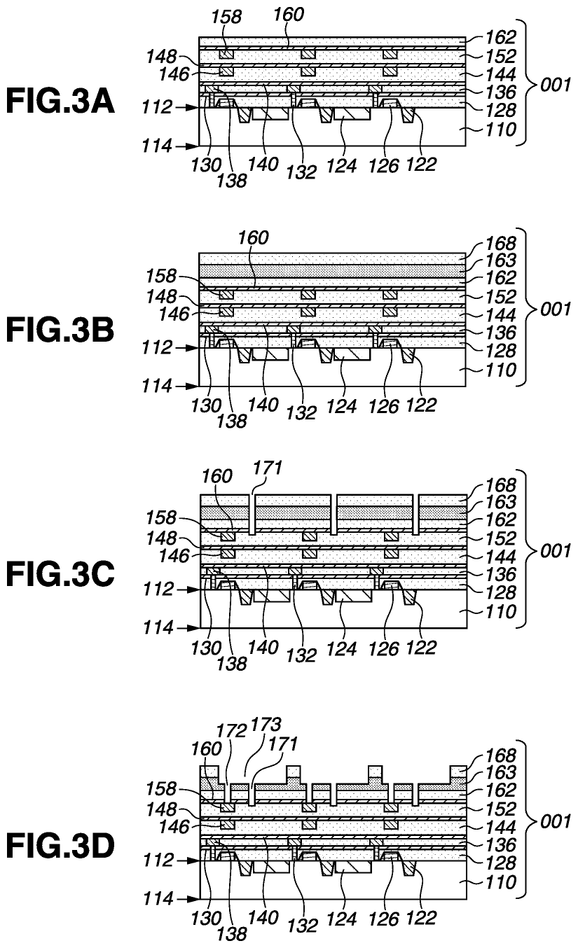

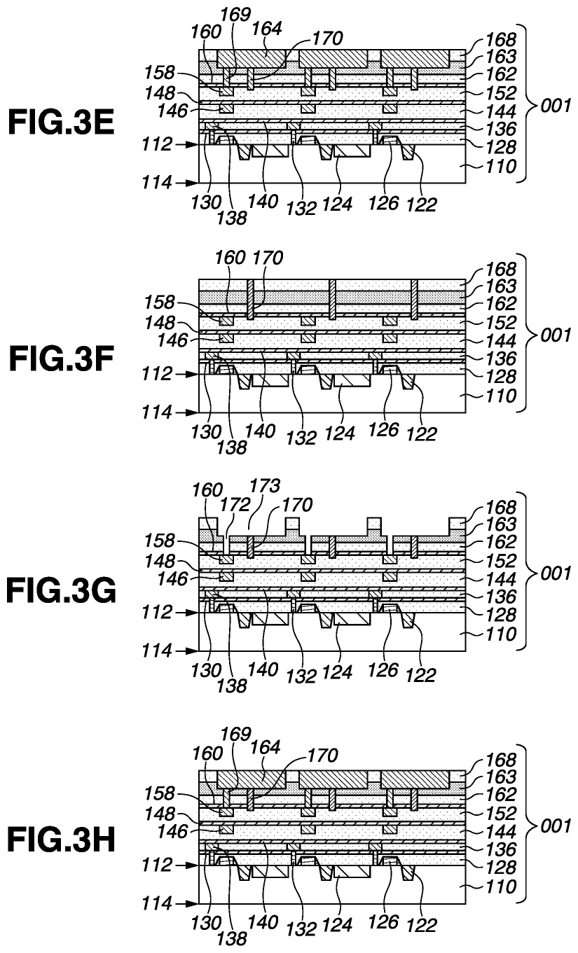

However, the second wiring layers 138, 146, and 158 include the metal, such as copper or cobalt, so that the second wiring layers 138, 146, and 158 will be oxidized if the heat treatment is performed with the second wiring layers 138, 146, and 158 exposed. Thus, as illustrated in FIG. 3B described below, the heat treatment is to be performed in a state where the second insulating film 160 is formed on entire surfaces of the second wiring layers 138, 146, and 158.

Meanwhile, in that state, hydrogen supply from the insulating films 162, 163, and 168 is inhibited by the second insulating film 160, and sufficient hydrogen cannot be used for dangling bond termination.

As a result, the noise and dark current generated near the photoelectric conversion unit 124 cannot be sufficiently reduced.

From this point of view, the photoelectric conversion apparatus according to the present exemplary embodiment is configured such that the entire end portion of the hole portion 170 on the second semiconductor layer 120 side of the second insulating film 160 is in contact with the third insulating film 152.

In other words, the hole portion 170 not in contact with the second wiring layers 138, 146, and 158 is arranged to penetrate through the first insulating film 162, the second insulating film 160, and the fourth insulating film 163, and forms the hydrogen supply path from the insulating films 162, 163, and 168 to the photoelectric conversion unit 124.

The above-described configuration makes it possible to supply sufficient hydrogen to the photoelectric conversion unit 124 with the heat treatment. This configuration enhances the effect of hydrogen termination of dangling bonds and reduces noise and dark current occurring near the photoelectric conversion unit 124 while reducing oxidation of the wiring layer including the metal in the heat treatment.

A method of arranging the hole portion 170 is appropriately selectable in accordance with a relationship between the capacity of supplying hydrogen to the photoelectric conversion unit 124 and a noise reduction effect, as long as at least a part of the second insulating film 160 is opened and the hole portion 170 is not in contact with the second wiring layers 138, 146, and 158. A similar configuration is applied to a case where a total number of the insulating films that inhibit the diffusion of hydrogen is five or more.

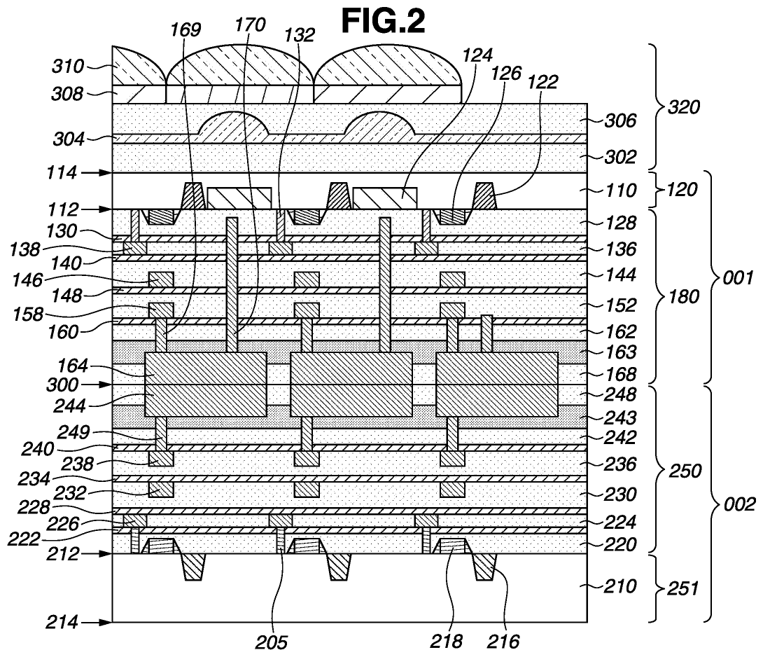

FIG. 2 illustrates a modification of the first exemplary embodiment. In the modification, the hole portion 170 not in contact with the second wiring layers 138, 146, and 158 may be provided to penetrate through the insulating films 130, 136, 140, 144, 148, 152, 160, 162, 163, and 168. In the present modification, in a case where the hole portion 170 is vertically projected onto a projection surface parallel to the second front surface 112, a part of the end portion of the hole portion 170 on the second semiconductor layer 120 side of the second insulating film 160 may be provided at a position overlapping the photoelectric conversion unit 124 on the projection surface.

In the present modification, the hole portion 170 penetrates through the insulating film 130, which is a hydrogen diffusion inhibition film closest to the photoelectric conversion unit 124, so that a physical distance between the hole portion 170 and the photoelectric conversion unit 124 is shortened. As a result, it is possible to supply sufficient hydrogen from the insulating films 162, 163, and 168 to the photoelectric conversion unit 124 more effectively with the heat treatment.

In other words, the dangling bond termination effect by hydrogen is enhanced with the configuration in which the end portion of the hole portion 170 facing the second semiconductor layer 120 is arranged toward the second front surface 112 with respect to an end portion of the second contact plug 132 facing the circuit substrate 002. Thus, the noise and dark current occurring near the photoelectric conversion unit 124 can be effectively reduced.

In FIGS. 1 and 2, the insulating films 220, 224, 230, 236, 242, 243, and 248 may also be used as the hydrogen supply sources, but the insulating films 222, 228, 234, 240, and 243 including the second insulating material inhibit the diffusion of hydrogen. However, the first wiring layers 226, 232, and 238 are each electrically connected by vias (not illustrated), and contact portions between the vias (not illustrated) and the wiring layers serve as the supply paths for hydrogen from the insulating films 220, 224, and 230. Further, a first via 249, the first wiring layer 244, the second via 169, and the second wiring layer 164 serve as the supply path for hydrogen from the insulating films 242, 243, and 248.

As described above, hydrogen released from the insulating films 220, 224, 230, 236, 242, 243, and 248 reaches the photoelectric conversion unit 124 through the above-described supply paths, thus hydrogen-terminating the dangling bond on the second front surface 112 side of the second semiconductor layer 120.

Next, the manufacturing method of the photoelectric conversion apparatus according to the present exemplary embodiment is described with reference to FIGS. 3A to 5C. FIGS. 3A to 5C are cross-sectional views in processes indicating the manufacturing method of the photoelectric conversion apparatus according to the present exemplary embodiment.

Initially, a method of forming the pixel substrate 001 is described with reference to FIGS. 3A, 3B, 3C, 3D, 3E, 3F, 3G, and 3H.

In a process A (a first process) illustrated in FIG. 3A, the second semiconductor substrate 110 is prepared as a base material of the pixel substrate 001. The second semiconductor substrate 110 is, for example, a silicon substrate and includes the pair of the second front surface 112 and the second back surface 114 that form opposite outer surfaces.

Next, the second element isolation unit 122 and the photoelectric conversion unit 124 are formed between the second front surface 112 and the second back surface 114 through a known semiconductor apparatus manufacturing process. Further, the MOS transistor including the second gate electrode 126, the insulating films 128 and 130, the second contact plug 132, and other elements are formed on the second front surface 112 side of the second semiconductor substrate 110 through the known semiconductor apparatus manufacturing process.

The insulating film 128 can be made of, for example, silicon oxide. The insulating film 130 can be made of, for example, silicon carbide. For example, silicon oxide is deposited on the second front surface 112 of the second semiconductor substrate 110 by a chemical vapor deposition (CVD) method, and a surface of the silicon oxide is then planarized to form the insulating film 128 made of a silicon oxide film. Next, silicon carbide is deposited on the insulating film 128 by the CVD method to form the insulating film 130 made of a silicon carbide film.

The insulating film 128 may be made of a silicon oxycarbide film and may include at least one of silicon oxide and silicon oxycarbide. The insulating film 130 may be made of a silicon nitride film or a silicon carbonitride film and may include at least one of silicon carbide, silicon nitride, and silicon carbonitride.

The second contact plug 132 can be made of, for example, tungsten and a barrier metal, such as titanium and titanium nitride. For example, a contact hole reaching the second semiconductor substrate 110 and/or the second gate electrode 126 is formed in the insulating films 128 and 130 by photolithography and dry etching. Next, after depositing a barrier metal film and a tungsten film by a sputtering method or the CVD method, the barrier metal film and the tungsten film on the insulating film 130 are removed by a chemical mechanical polishing (CMP) method or etch-back, and the second contact plug 132 embedded in the contact hole is formed.

Next, the insulating film 136, the second wiring layer 138 arranged in the insulating film 136, and the insulating film 140 arranged on the insulating film 136 and the second wiring layer 138 are formed on the insulating film 130 through the known semiconductor apparatus manufacturing process.

The insulating film 136 can be made of, for example, silicon oxide. The second wiring layer 138 can be made of, for example, the conductive material including metals, such as copper and cobalt. The insulating film 140 can be made of, for example, silicon carbide. For example, silicon oxide is deposited on the insulating film 130 by the CVD method to form the insulating film 136 made of a silicon oxide film.

Next, the second wiring layer 138 made of the conductive material including metals, such as copper and cobalt, is formed in the insulating film 136 by a known single damascene process. The insulating film 130 has the role as the etching stopper film at the time of forming a wiring groove in which the second wiring layer 138 is embedded and the role as the diffusion prevention film for a component material of the second wiring layer 138.

Next, silicon carbide is deposited on the insulating film 136 and the second wiring layer 138 by, for example, the CVD method to form the insulating film 140 made of a silicon carbide film.

The insulating film 136 may be made of a silicon oxycarbide film and may include at least one of silicon oxide and silicon oxycarbide. The insulating film 140 may be made of a silicon nitride film or a silicon carbonitride film and may include at least one of silicon carbide, silicon nitride, and silicon carbonitride.

Next, the insulating film 144, the second wiring layer 146 arranged in the insulating film 144, and the insulating film 148 arranged on the insulating film 144 and the second wiring layer 146 are formed over the insulating film 140 through the known semiconductor apparatus manufacturing process.

The insulating film 144 can be made of, for example, silicon oxide. The second wiring layer 146 can be made of, for example, the conductive material including metals, such as copper and cobalt. The insulating film 148 can be made of, for example, silicon carbide. For example, silicon oxide is deposited on the insulating film 140 by the CVD method to form the insulating film 144 made of a silicon oxide film.

Next, the second wiring layer 146 made of the conductive material including metals, such as copper and cobalt, is formed in the insulating film 144 by a known dual damascene process. The insulating film 148 has the role as the diffusion prevention film for the component material of the second wiring layers 138 and 146. Next, silicon carbide is deposited on the insulating film 144 and the second wiring layer 146 by, for example, the CVD method to form the insulating film 148 made of a silicon carbide film.

The insulating film 144 may be made of a silicon oxycarbide film and may include at least one of silicon oxide and silicon oxycarbide. The insulating film 148 may be made of a silicon nitride film or a silicon carbonitride film and may include at least one of silicon carbide, silicon nitride, and silicon carbonitride.

Next, the insulating film 152, the second wiring layer 158 arranged in the insulating film 152, the second insulating film 160 arranged on the insulating film 152 and the second wiring layer 158, and the first insulating film 162 arranged on the second insulating film 160 are formed over the insulating film 148 by a known semiconductor apparatus manufacturing process.

The insulating films 152 and 162 can be made of, for example, silicon oxide. The second wiring layer 158 can be made of, for example, the conductive material including metals, such as copper and cobalt. The second insulating film 160 can be made of, for example, silicon carbide. For example, silicon oxide is deposited on the insulating film 148 by the CVD method to form the insulating film 152 made of a silicon oxide film.

Next, the second wiring layer 158 made of the conductive material including metals, such as copper and cobalt, is formed in the insulating film 152 through the known dual damascene process. The second insulating film 160 has the role as the diffusion prevention film for the component material of the second wiring layers 138, 146, and 158.

Next, silicon carbide is deposited on the insulating film 152 and the second wiring layer 158 by, for example, the CVD method to form the second insulating film 160 made of a silicon carbide film. Next, silicon oxide is deposited on the second insulating film 160 by, for example, the CVD method to form the first insulating film 162 made of a silicon oxide film.

The insulating films 152 and 162 may be made of silicon oxycarbide films and may include at least one of silicon oxide and silicon oxycarbide. The second insulating film 160 may be made of a silicon nitride film or a silicon carbonitride film and may include at least one of silicon carbide, silicon nitride, and silicon carbonitride.

In a process B illustrated in FIG. 3B, the insulating films 163 and 168 are formed over the first insulating film 162 by a known semiconductor apparatus manufacturing process.

The fourth insulating film 163 can be made of, for example, silicon nitride. The insulating film 168 can be made of, for example, silicon oxide. The fourth insulating film 163 may be made of a silicon oxycarbide film and may include at least one of silicon nitride and silicon oxycarbide. The insulating film 168 may be made of a silicon oxycarbide film and may include at least one of silicon oxide and silicon oxycarbide.

In a process C (second and third processes) illustrated in FIG. 3C, an opening portion 171 penetrating through the insulating films 160, 162, 163, and 168 is formed so as not to be in contact with the second wiring layer 158 by photolithography and dry etching. In other words, the opening portion 171 is formed in such a manner that an entire end portion of the opening portion 171 on the second semiconductor substrate 110 (the second semiconductor layer 120) side of the second insulating film 160 is in contact with the third insulating film 152.

The opening portion 171 may penetrate through the insulating films 130, 136, 140, 144, 148, 152, 160, 162, 163, and 168 so as not to be in contact with the second wiring layers 138, 146, and 158. In this case, in a case where the opening portion 171 is vertically projected onto the projection surface parallel to the second front surface 112, a part of the end portion of the opening portion 171 on the second semiconductor substrate 110 (the second semiconductor layer 120) side of the second insulating film 160 may be formed at a position overlapping the photoelectric conversion unit 124 on the projection surface.

After forming the opening portion 171, the pixel substrate 001 including the first insulating film 162 is subjected to the heat treatment in a nitrogen atmosphere or a hydrogen-containing atmosphere (e.g., a forming gas atmosphere). Hydrogen is released from the insulating films 128, 136, 144, 152, 162, 163, and 168 through this heat treatment. Meanwhile, the insulating films 130, 140, 148, 160, and 163 have the property of inhibiting diffusion of hydrogen.

The released hydrogen reaches the photoelectric conversion unit 124 through an opening of the second insulating film 160 resulting from the opening portion 171 and contact portions between vias (not illustrated) connecting each of the second wiring layers 138, 146, and 158 and the wiring layers. As a result, sufficient hydrogen is supplied to terminate the dangling bond on the second front surface 112 side of the second semiconductor layer 120.

The opening portion 171 is formed so as not to be in contact with the second wiring layers 138, 146, and 158, and an entire surfaces of the second wiring layers 138, 146, and 158 are covered with the second insulating film 160, thus preventing oxidation of the second wiring layers 138, 146, and 158 due to the heat treatment. In addition, the heat treatment for adjusting a hydrogen supply amount becomes performable on the pixel substrate 001 without application thereof to the circuit substrate 002, so that a degree of freedom in processes, such as the heat treatment, increases.

The insulating films 128, 136, 144, 152, 162, 163, and 168 having the property of supplying hydrogen to the photoelectric conversion unit 124 may be formed by a film forming apparatus using plasma, such as a parallel flat plate plasma CVD apparatus and a high density plasma CVD apparatus. In this case, a content of hydrogen in these insulating films increases.

In a process D illustrated in FIG. 3D, an opening portion 172 for the second via 169 and an opening portion 173 for the second wiring layer 164, which are arranged in the insulating films 162, 163, and 168, are formed by a known semiconductor apparatus manufacturing process. The opening portion 172 for the second via 169 is formed to penetrate through the insulating films 160, 162, 163, and 168 and to be in contact with the second wiring layer 158.

In a process E (a fifth process) illustrated in FIG. 3E, the opening portion 171, the opening portion 172 for the second via 169, and the opening portion 173 for the second wiring layer 164 are filled with the conductive material including metals, such as copper and cobalt, by, for example, the known dual damascene process. As a result, the second wiring layer 164, the second via 169, and the hole portion 170 can be formed. The fourth insulating film 163 has the role as the etching stopper film at the time of forming a wiring groove in which the second wiring layer 164 is embedded and the role as the diffusion prevention film for the component material of the second wiring layers 138, 146, 158, and 164.

The opening portion 171 may be filled with an insulating material, such as silicon oxide, to form the hole portion 170, and, in such a case, processes F, G, and H are performable subsequent to the process C. However, in a case where the opening portion 171 is filled with the insulating material, such as silicon oxide, the number of processes may be increased compared with a case where the opening portion 171 is filled with the conductive material including metals, such as copper and cobalt.

In the process F (a sixth process) illustrated in FIG. 3F, the opening portion 171 is filled with the insulating material such as silicon oxide by, for example, the known dual damascene process, and thus the hole portion 170 is formed.

In the process G illustrated in FIG. 3G, the opening portion 172 for the second via 169 and the opening portion 173 for the second wiring layer 164, which are arranged in the insulating films 162, 163, and 168, are formed by, for example, the known semiconductor apparatus manufacturing process.

In the process H illustrated in FIG. 3H, the opening portion 172 for the second via 169 and the opening portion 173 for the second wiring layer 164 are filled with the conductive material including metals, such as copper and cobalt, by, for example, the known dual damascene process. As a result, it is possible to form the second wiring layer 164 and the second via 169. The fourth insulating film 163 has the role as the etching stopper film at the time of forming the wiring groove in which the second wiring layer 164 is embedded and the role as the diffusion prevention film for the component material of the second wiring layers 138, 146, 158, and 164.

As described above, the pixel substrate 001 including a photoelectric conversion element before bonding is completed.

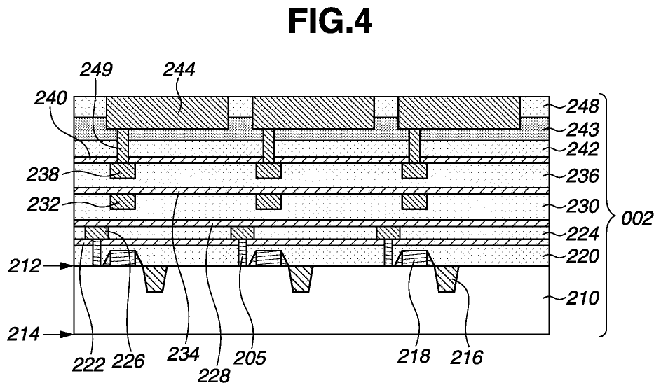

Next, the manufacturing method for the circuit substrate 002 is described with reference to FIG. 4. Initially, apart from the pixel substrate 001, the first semiconductor substrate 210 is prepared as a base material for the circuit substrate 002. The first semiconductor substrate 210 is, for example, a silicon substrate and includes the pair of the first front surface 212 and the first back surface 214 that form opposite outer surfaces.

Next, the first element isolation unit 216, the MOS transistor including the first gate electrode 218, the insulating films 220 and 222, the first contact plug 205, and the like are formed on the first front surface 212 side of the first semiconductor substrate 210 by a known semiconductor apparatus manufacturing process.

Next, the insulating film 224, the first wiring layer 226 arranged in the insulating film 224, the insulating film 228 arranged on the insulating film 224 and the first wiring layer 226, and the like are formed over the insulating film 222 by a known semiconductor apparatus manufacturing process.

Next, the insulating film 230, the first wiring layer 232 arranged in the insulating film 230, the insulating film 234 arranged on the insulating film 230 and the first wiring layer 232, and the like are formed over the insulating film 228 by a known semiconductor apparatus manufacturing process.

Next, the insulating film 236, the first wiring layer 238 arranged in the insulating film 236, the insulating film 240 arranged on the insulating film 236 and the first wiring layer 238, and the like are formed over the insulating film 234 by a known semiconductor apparatus manufacturing process.

Next, the insulating films 242, 243, and 248, the first wiring layer 244 arranged in the insulating films 242, 243, and 248, and the like are formed over the insulating film 240 by a known semiconductor apparatus manufacturing process.

The insulating films 220, 224, 230, 236, 242, and 248 can be made of, for example, silicon oxide. The insulating film 243 can be made of, for example, silicon nitride. The insulating film 243 has the role as the etching stopper film at the time of forming a wiring groove in which the first wiring layer 244 is embedded and the role as the diffusion prevention film for a component material of the first wiring layers 226, 232, 238, and 244.

The insulating films 222, 228, 234, and 240 can be made of, for example, silicon carbide.

The first contact plug 205 can be made of, for example, tungsten and a barrier metal, such as titanium or titanium nitride.

The first wiring layers 226, 232, 238, and 244 can be made of, for example, the conductive material including metals, such as copper and cobalt, by a known single damascene process. The insulating film 222 has the role as the etching stopper film at the time of forming a wiring groove in which the first wiring layer 226 is embedded and the role as the diffusion prevention film with respect to the component material of the first wiring layer 226. The insulating films 228, 234, and 240 have the role as the diffusion prevention films for the component material of the first wiring layers 226, 232, and 238.

The insulating films 220, 224, 230, 236, and 242 may be made of silicon oxycarbide films and may include at least one of silicon oxide and silicon oxycarbide.

The insulating film 243 may be made of a silicon oxycarbide film and may include at least one of silicon nitride and silicon oxycarbide. Further, the insulating films 222, 228, 234, and 240 may be made of silicon nitride films or silicon carbonitride films and may include at least one of silicon carbide, silicon nitride, and silicon carbonitride.

Through these processes, the circuit substrate 002 before bonding is completed.

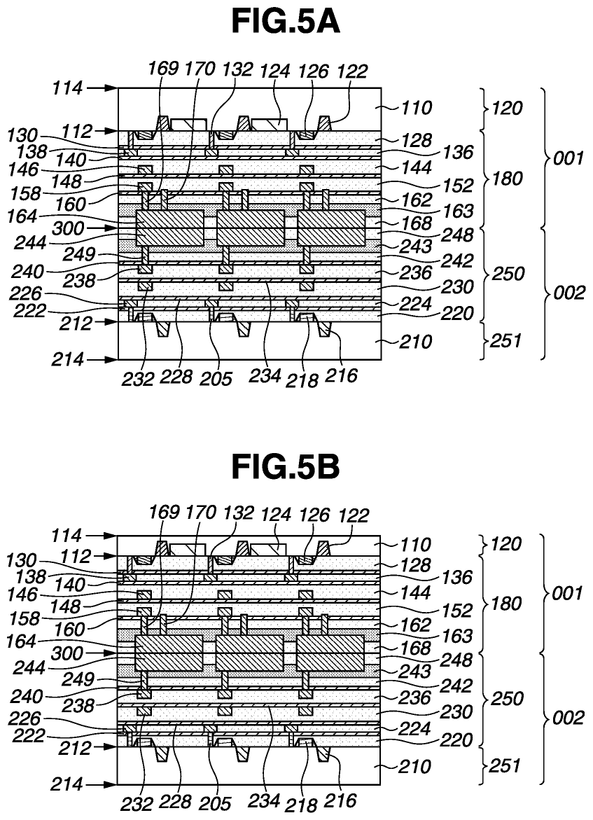

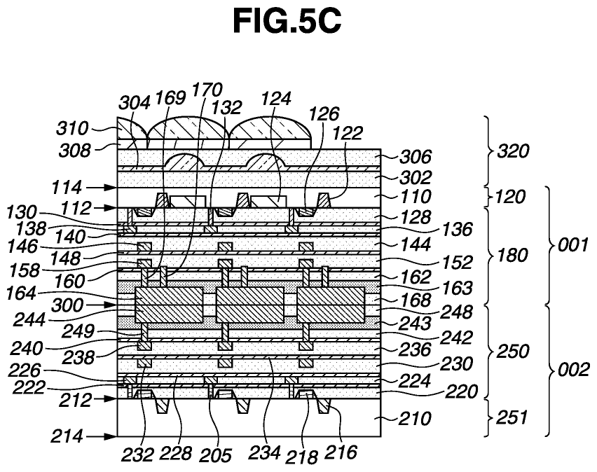

In a process I (a fourth process) illustrated in FIG. 5A, the formed pixel substrate 001 and circuit substrate 002 are arranged to face each other in such a manner that the insulating films 168 and 248 face each other, and the circuit substrate 002 is bonded to the second front surface 112 side of the second semiconductor layer 120. Accordingly, the second wiring layer 164 of the pixel substrate 001 and the first wiring layer 244 of the circuit substrate 002 are electrically connected on a bonding surface 300 between the pixel substrate 001 and the circuit substrate 002. The pixel substrate 001 and the circuit substrate 002 may be bonded together using a method for bonding insulating films of silicon oxide or the like with each other or a bonding method including a metal wiring of copper or cobalt in part.

In a process J illustrated in FIG. 5B, the second semiconductor substrate 110 in the pixel substrate 001 is thinned to a predetermined thickness from the second back surface 114 to form the second semiconductor layer 120 obtained by thinning the second semiconductor substrate 110. For thinning the second semiconductor substrate 110, back grinding, CMP, etching, and other methods are applicable. Alternatively, it is also possible to apply other known substrate thinning techniques, which are adopted in three-dimensional mounting, a through-silicon via (TSV) formation process, and the like. In the following description, a new surface of the second semiconductor layer 120 exposed by thinning the second semiconductor substrate 110 is also referred to as the second back surface 114 for convenience sake.

Next, the heat treatment is performed in the nitrogen atmosphere or the hydrogen-containing atmosphere (e.g., the forming gas atmosphere). Hydrogen is released from the insulating films 128, 136, 144, 152, 162, 163, 168, 220, 224, 230, 236, 242, 243, and 248 by the heat treatment. The hydrogen thus released reaches the photoelectric conversion unit 124 through the first wiring layers 226, 232, 238, and 244, the second wiring layers 138, 146, 158, and 164, vias (not illustrated) connecting each of the first wiring layers 226, 232, and 238, vias (not illustrated) connecting each of the second wiring layers 138, 146, and 158, the first via 249, and the second via 169.

Thus, the dangling bond on the second front surface 112 side of the second semiconductor layer 120 can be terminated with hydrogen.

Timing for performing the heat treatment is not limited to the timing after thinning the second semiconductor substrate 110. The heat treatment at the time of bonding the pixel substrate 001 and the circuit substrate 002 may be adopted, or the heat treatment may be performed before or after forming the insulating film 302, the interlayer lens 304, the insulating film 306, and the like described in FIG. 5C. In a case where hydrogen can be diffused sufficiently to the photoelectric conversion unit 124 due to a heat history of a back-end process, it is not always necessary to perform the heat treatment separately.

In a process K illustrated in FIG. 5C, the insulating film 302, the interlayer lens 304, the insulating film 306, the color filter layer 308, the microlens 310, and the like are formed on the second back surface 114 of the second semiconductor layer 120 by a known photoelectric conversion apparatus manufacturing process. Through the above-described processes, the photoelectric conversion apparatus according to the present exemplary embodiment is completed.

As described above, the present exemplary embodiment reduces oxidation of the wiring layer including a metal in the heat treatment, promotes supply of hydrogen to the photoelectric conversion unit, and effectively reduces noise resulting from influence of a crystal defect in silicon and an interface state between silicon and the insulating film.

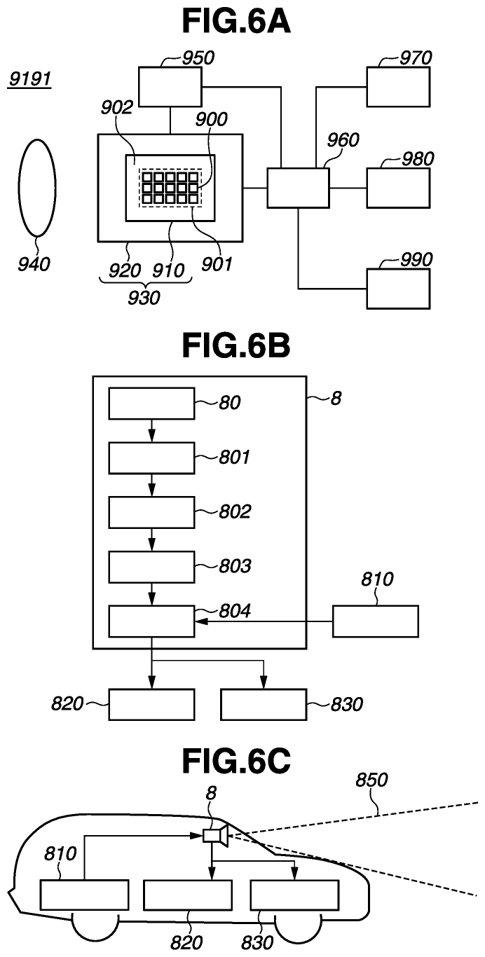

A second exemplary embodiment of the present disclosure will be described below. The second exemplary embodiment is applicable to the first exemplary embodiment. FIG. 6A is a schematic diagram illustrating a device 9191 including a semiconductor apparatus 930 according to the present exemplary embodiment. The photoelectric conversion apparatus (an image capturing apparatus) according to each of the above-described exemplary embodiments is useable for the semiconductor apparatus 930. The device 9191 including the semiconductor apparatus 930 is described in detail. The semiconductor apparatus 930 can include a semiconductor device 910. The semiconductor device 910 has a pixel area 901 in which a pixel circuit 900 including a photoelectric conversion unit is arranged in a matrix. The semiconductor device 910 can have a peripheral area 902 around the pixel area 901. Circuits other than the pixel circuit 900 can be arranged in the peripheral area 902. The semiconductor apparatus 930 can include a semiconductor device 910 and also a package 920 storing the semiconductor device 910 as described above. The package 920 can include a base member to which the semiconductor device 910 is fixed and a lid body, such as glass, facing the semiconductor device 910. The package 920 can further include bonding members, such as a bonding wire and a bump, for connecting a terminal provided on the base member and a terminal provided on the semiconductor device 910.

The device 9191 can include at least any one of an optical apparatus 940, a control apparatus 950, a processing apparatus 960, a display apparatus 970, a storage apparatus 980, and a mechanical apparatus 990. The optical apparatus 940 corresponds to the semiconductor apparatus 930. The optical apparatus 940 is, for example, a lens, a shutter, and a mirror. The control apparatus 950 controls the semiconductor apparatus 930. The control apparatus 950 is, for example, a semiconductor apparatus, such as an application specific integrated circuit (ASIC).

The processing apparatus 960 processes a signal output from the semiconductor apparatus 930. The processing apparatus 960 is a semiconductor apparatus, such as a central processing unit (CPU) and an ASIC, for constructing an analog front end (AFE) or a digital front end (DFE). The display apparatus 970 is an electroluminescence (EL) display apparatus or a liquid crystal display apparatus that displays information (an image) obtained by the semiconductor apparatus 930. The storage apparatus 980 is a magnetic device or a semiconductor device that stores information (an image) obtained by the semiconductor apparatus 930. The storage apparatus 980 is a volatile memory, such as a static random access memory (SRAM) and a dynamic RAM (DRAM), or a nonvolatile memory, such as flash memory and a hard disk drive.

The mechanical apparatus 990 includes a movable unit or a propulsion unit such as a motor and an engine. In the device 9191, a signal output from the semiconductor apparatus 930 is displayed on the display apparatus 970 and is transmitted to the outside by a communication apparatus (not illustrated) included in the device 9191. Thus, it is desirable that the device 9191 further includes the storage apparatus 980 and the processing apparatus 960 separately from a memory circuit and a calculation circuit included in the semiconductor apparatus 930. The mechanical apparatus 990 may be controlled based on a signal output from the semiconductor apparatus 930.

The device 9191 is suitable for electronic devices including, but not limited to an information terminal (e.g., a smartphone and a wearable terminal) having an image capturing function and a camera (e.g., an interchangeable lens camera, a compact camera, a video camera, and a surveillance camera). The mechanical apparatus 990 in the camera is capable of driving a component of the optical apparatus 940 for zooming, focusing, and shuttering operation. Alternatively, the mechanical apparatus 990 in the camera is capable of moving the semiconductor apparatus 930 for an anti-vibration operation.

The device 9191 can be a transportation device, such as a vehicle, a ship, and a flight vehicle. The mechanical apparatus 990 in the transportation device can be used as a movement apparatus. The device 9191 as the transportation device is suitable for transporting the semiconductor apparatus 930 or for assisting and/or automating driving (steering) using an image capturing function. The processing apparatus 960 for assisting and/or automating driving (steering) can perform processing for driving the mechanical apparatus 990 serving as the movement apparatus based on information obtained by the semiconductor apparatus 930. Alternatively, the device 9191 may be a medical device, such as an endoscope, a measuring device, such as a ranging sensor, an analytical instrument, such as an electron microscope, office equipment, such as a copying machine, and industrial equipment, such as a robot.

According to the above-described exemplary embodiments, it is possible to obtain favorable pixel characteristics. Therefore, a value of the semiconductor apparatus can be increased. Increasing the value described here includes at least any one of adding a function, improving performance, improving a characteristic, improving reliability, improving a manufacturing yield, reducing an environmental burden, cost reduction, miniaturization, and weight reduction.

Thus, the value of the device 9191 can be improved by including the semiconductor apparatus 930 according to the present exemplary embodiment in the device 9191. For example, the semiconductor apparatus 930 is installed in a transportation device, and excellent performance can be acquired in capturing an image of an exterior of the transportation device and in measuring an external environment. Thus, in manufacture and sale of the transportation device, determining to mount the semiconductor apparatus according to the present exemplary embodiment in the transportation device is advantageous to improve the performance of the transportation device itself. In particular, the semiconductor apparatus 930 is suitable for operation assistance of a transportation device and/or for a transportation device that performs automatic operation using information obtained by the semiconductor apparatus.

A photoelectric conversion system and a mobile body according to the present exemplary embodiment are described with reference to FIGS. 6B and 6C.

FIG. 6B illustrates an example of a photoelectric conversion system relating to an on-vehicle camera. A photoelectric conversion system 8 includes a photoelectric conversion apparatus 80. The photoelectric conversion apparatus 80 is the photoelectric conversion apparatus (an image capturing apparatus) according to any of the above-described exemplary embodiments. The photoelectric conversion system 8 includes an image processing unit 801 that performs image processing on a plurality pieces of image data obtained by the photoelectric conversion apparatus 80 and a parallax acquisition unit 802 that calculates parallax (a phase difference in parallax images) from the plurality of image data obtained by the photoelectric conversion system 8. The photoelectric conversion system 8 also includes a distance acquisition unit 803 that calculates a distance to an object based on the calculated parallax and a collision determination unit 804 that determines whether there is a possibility of collision based on the calculated distance. The parallax acquisition unit 802 and the distance acquisition unit 803 are examples of a distance information acquisition unit that acquires distance information to an object. In other words, the distance information is information about parallax, a defocus amount, a distance to an object, and the like. The collision determination unit 804 may use any of the distance information to determine the possibility of collision. The distance information acquisition unit may be realized by specifically designed hardware or by a software module. The distance information acquisition unit may also be realized by a field programmable gate array (FPGA), an ASIC, or a combination of them.

The photoelectric conversion system 8 is connected to a vehicle information acquisition apparatus 810 and can acquire vehicle information, such as a vehicle speed, a yaw rate, and a steering angle. The photoelectric conversion system 8 is also connected to a control engine control unit (ECU) 820, which is a control unit that outputs a control signal for generating a braking force to the vehicle based on a determination result of the collision determination unit 804. The photoelectric conversion system 8 is also connected to an alarm apparatus 830 that issues an alarm to a driver based on the determination result of the collision determination unit 804. For example, if there is a high possibility of collision from the determination result of the collision determination unit 804, the control ECU 820 controls the vehicle to avoid collision and reduce damage by applying the brake, releasing an accelerator, and suppressing an engine output. The alarm apparatus 830 warns a user by sounding the alarm, displaying alarm information on a screen of a car navigation system or the like, and vibrating a seatbelt and a steering wheel.

According to the present exemplary embodiment, the photoelectric conversion system 8 captures an image of surroundings, for example, ahead or behind of the vehicle.

FIG. 6C illustrates the photoelectric conversion system 8 in a case where an image ahead of the vehicle (an imaging range 850) is captured. The vehicle information acquisition apparatus 810 transmits an instruction to the photoelectric conversion system 8 or the photoelectric conversion apparatus 80. The above-described configuration improves accuracy of distance measurement.

While the example of controlling the vehicle so as not to collide with another vehicle has been described above, the present exemplary embodiment is also applicable to control for automatically driving a vehicle following another vehicle and control for automatically driving a vehicle so as not to stray from a lane. Moreover, the photoelectric conversion system can be applied not only to a vehicle, such as an automobile, but also to a mobile body (a movable apparatus) such as a ship, an aircraft, or an industrial robot. In addition, the photoelectric conversion system can be applied not only to a mobile body, but also to a device that widely uses object recognition, such as intelligent transportation systems (ITS).

The exemplary embodiments described above can be modified as appropriate without departing from the technical concept. The disclosure of the present specification includes not only what is explicitly described in the present specification, but also all matters that can be understood from the present specification and the drawings attached thereto. Further, the disclosure of the present specification includes complements of the concepts described in the present specification. More specifically, if the present specification includes a description to the effect that, for example, “A is greater than B”, even if a description to the effect that “A is not greater than B” is omitted, it can be said that the present specification still describes that “A is not greater than B”. This is because the description that “A is greater than B” assumes a case where “A is not greater than B”.

According to the present disclosure, noise and dark current resulting from influence of a crystal defect in silicon and an interface state between silicon and an insulating film can be effectively reduced while reducing oxidation of a wiring layer including a metal in heat treatment.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-091508, filed Jun. 6, 2022, which is hereby incorporated by reference herein in its entirety.

What is claimed is:

1. A photoelectric conversion apparatus, comprising:
a semiconductor layer having a front surface and a back surface and including a photoelectric conversion unit between the front surface and the back surface;
a circuit substrate arranged closer to the front surface than to the back surface;
a first insulating film arranged between the front surface and the circuit substrate;
a second insulating film arranged between the front surface and the first insulating film;
a third insulating film arranged between the front surface and the second insulating film; and
a wiring layer arranged between the front surface and the second insulating film,
wherein the first insulating film includes at least one of silicon oxide and silicon oxycarbide,
wherein the second insulating film includes at least one of silicon carbide, silicon nitride, and silicon carbonitride,
wherein a hole portion provided with a conductive material and penetrating through the first insulating film and the second insulating film is disposed, and
wherein an entire end portion of the hole portion on the semiconductor layer side of the second insulating film is in contact with the third insulating film.

2. The photoelectric conversion apparatus according to claim 1, wherein the photoelectric conversion apparatus has a via provided with the conductive material and penetrating through the first insulating film and the second insulating film, and the via is in contact with the wiring layer.

3. The photoelectric conversion apparatus according to claim 1, wherein the first insulating film has a property of supplying hydrogen, and the second insulating film has a property of inhibiting diffusion of hydrogen.

4. The photoelectric conversion apparatus according to claim 1, wherein the third insulating film includes at least one of silicon oxide and silicon oxycarbide.

5. The photoelectric conversion apparatus according to claim 1, wherein a fourth insulating film is arranged between the circuit substrate and the first insulating film, the fourth insulating film includes at least one of silicon nitride and silicon oxycarbide, and the hole portion penetrates through the fourth insulating film.

6. The photoelectric conversion apparatus according to claim 5, wherein the first insulating film and the fourth insulating film have a property of supplying hydrogen, and the second insulating film has a property of inhibiting diffusion of hydrogen.

7. The photoelectric conversion apparatus according to claim 1, wherein a contact plug is disposed closer to the front surface than to the back surface, and the end portion of the hole portion is disposed toward the front surface with respect to an end portion of the contact plug facing the circuit substrate.

8. The photoelectric conversion apparatus according to claim 7, wherein, in vertical projection onto a projection surface parallel to the front surface, a part of the end portion of the hole portion overlaps the photoelectric conversion unit on the projection surface.

9. A method for manufacturing a photoelectric conversion apparatus including
a semiconductor layer having a front surface and a back surface and including a photoelectric conversion unit between the front surface and the back surface,
a circuit substrate arranged closer to the front surface than to the back surface,
a first insulating film arranged between the front surface and the circuit substrate,
a second insulating film arranged between the front surface and the first insulating film,
a third insulating film arranged between the front surface and the second insulating film, and
a wiring layer arranged between the front surface and the second insulating film, the method comprising:
a first process of forming the wiring layer, the second insulating film including at least one of silicon carbide, silicon nitride, and silicon carbonitride, and the first insulating film including at least one of silicon oxide and silicon oxycarbide, in this order;
a second process of forming, after the first process, an opening portion penetrating through the first insulating film and the second insulating film in such a manner that an entire end portion of the opening portion on the semiconductor layer side of the second insulating film is in contact with the third insulating film after the first process;
a third process of heat treating the first insulating film after the second process; and
a fourth process of bonding the circuit substrate to a portion closer to the front surface than to the back surface after the third process.

10. The method according to claim 9, further comprising a fifth process of forming, after the third process, a via in which a conductive material is provided to penetrate through the first insulating film and the second insulating film and to be in contact with the wiring layer.

11. The method according to claim 10, wherein the fifth process includes a process of forming a hole portion by filling the opening portion with the conductive material.

12. The method according to claim 9, further comprising a sixth process of forming a hole portion by filling the opening portion with an insulating material, after the third process.

13. The method according to claim 9, wherein the first insulating film has a property of supplying hydrogen, and the second insulating film has a property of inhibiting diffusion of hydrogen.

14. The method according to claim 9, wherein the third insulating film includes at least one of silicon oxide and silicon oxycarbide.

15. The method according to claim 9,
wherein the first process includes a process of forming a fourth insulating film including at least one of silicon nitride and silicon oxycarbide to cover the first insulating film after forming the first insulating film, and
wherein the second process includes a process of forming the opening portion to penetrate through the fourth insulating film.

16. The method according to claim 15, wherein the first insulating film and the fourth insulating film have a property of supplying hydrogen, and the second insulating film has a property of inhibiting diffusion of hydrogen.

17. A device provided with the photoelectric conversion apparatus according to claim 1, the device comprising at least any one of:
an optical apparatus compatible with the photoelectric conversion apparatus;
a control apparatus configured to control the photoelectric conversion apparatus;
a processing apparatus configured to process a signal output from the photoelectric conversion apparatus;
a display apparatus configured to display information obtained by the photoelectric conversion apparatus;
a storage apparatus configured to store the information obtained by the photoelectric conversion apparatus; and
a mechanical apparatus configured to operate based on the information obtained by the photoelectric conversion apparatus.

18. A substrate, comprising:
a semiconductor layer having a front surface and a back surface and including a photoelectric conversion unit between the front surface and the back surface;
a first insulating film arranged closer to the front surface than to the back surface;
a second insulating film arranged between the front surface and the first insulating film;
a third insulating film arranged between the front surface and the second insulating film; and
a wiring layer arranged between the front surface and the second insulating film,
wherein the substrate is to be laminated on a circuit substrate arranged closer to the front surface than to the back surface,
wherein the first insulating film includes at least one of silicon oxide and silicon oxycarbide,
wherein the second insulating film includes at least one of silicon carbide, silicon nitride, and silicon carbonitride,
wherein a hole portion provided with a conductive material and penetrating through the first insulating film and the second insulating film is disposed, and
wherein an entire end portion of the hole portion on the semiconductor layer side of the second insulating film is in contact with the third insulating film.
